(19) United States
(12) Patent Application Publication
(10) Pub. No.: US 2025/0392319 A1
(43) Pub. Date: Dec. 25, 2025

(54) DIGITAL-TO-ANALOG CONVERTER (DAC)

(71) Applicants: Rajesh Cheeranthodi, Bangaluru (IN); Gunjan Mandal, Bangalore (IN); Kishan PraDHAN, Kokrajhar (IN)

(72) Inventors: Rajesh Cheeranthodi, Bangaluru (IN); Gunjan Mandal, Bangalore (IN); Kishan PraDHAN, Kokrajhar (IN)

(21) Appl. No.: 18/753,485

(22) Filed: Jun. 25, 2024

(51) Int. Cl. H03M 1/46; H03M 1/80

(52) U.S. Cl. CPC H03M 1/468; H03M 1/464; H03M 1/804; H03M 1/808

(57) ABSTRACT

A digital-to-analog converter (DAC) apparatus includes a resistive DAC circuit and a capacitive DAC circuit coupled via a coupling capacitor. The resistive DAC circuit includes a first plurality of resistors coupled in parallel, and a first plurality of input switches coupled to the first plurality of resistors. The capacitive DAC circuit includes a plurality of capacitors coupled in parallel, and a second plurality of input switches coupled to the plurality of resistors. The coupling capacitor includes a first terminal coupled to the resistive DAC circuit and a second terminal coupled to the capacitive DAC circuit.

### BACKGROUND

The performance of an ADC is mainly dictated by the performance of its DAC circuit. In this regard, the speed and accuracy characteristics of the DAC can be configured to be higher than those of the ADC. For high-speed operations, it can be challenging to build a DAC with pre-configured speed and accuracy. This is due to the DAC elements needing better matching and, hence, larger sizes to achieve improvement in accuracy. However, larger element sizes cause slower operation speeds due to the larger parasitics associated with them. In this regard, the design of the DAC can be balanced between the two performance goals of accuracy and speed.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings listed below.

FIG. 1 is a block diagram of a capacitor-based DAC (C-DAC) with M+N bits resolution, in accordance with some embodiments.

FIG. 2 is a block diagram of a hybrid DAC structure with a resistive DAC and a C-DAC, effectively generating an equivalent M+N bits master DAC, in accordance with some embodiments.

FIG. 3 illustrates a graph of a 10-bit hybrid capacitive-resistive (C-R) DAC output with full code sweep, in accordance with some embodiments.

FIG. 4 illustrates a graph of a zoomed version of DAC output showing the LSB switching of C-DAC, in accordance with some embodiments.

FIG. 5 is a graph of the least significant bit (LSB) step change propagation delay across a 5-bit R-2R DAC up to the final DAC output, in accordance with some embodiments.

FIG. 6 is a graph of voltage settling across the coupling capacitance Cc for a C-DAC most significant bit (MSB) step change, in accordance with some embodiments.

FIG. 7 is a flow diagram of an example method for configuring a digital-to-analog converter (DAC) apparatus, in accordance with some embodiments.

FIG. 8 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “IO” indicates input/output. As used herein, the term “R-C” indicates resistance and capacitance. As used herein, the term “Rx” indicates receiver (or receive). As used herein, the term “Tx” indicates transmitter (or transmit). As used herein, the term “TRX” indicates transceiver. As used herein, the term “UCIe” indicates Universal Chiplet Interconnect Express. As used herein, the term “Vref” indicates reference voltage. As used herein, the term “Vin” indicates input voltage.

As used herein, the term “coupled in parallel” may mean direct or indirect parallel connection between components.

In some aspects, the disclosed techniques can be used to configure a high accuracy, high speed, power/area efficient DAC sub-block (e.g., as used by a SAR ADC or a pure/hybrid variant).

One of the power-efficient accurate DAC implementations that can be generally seen in SAR converter is a binary weighted capacitor DAC (C-DAC) structure. But, as the accuracy requirement increases (e.g., 8 bits), the binary-weighted array needs large capacitors to keep the random mismatch as per the required specification, as the mismatch number affects DAC's linearity exponentially. This occupies more area and parasitics and reduces the operating speed of the DAC (and the overall ADC that has it) to a great extent. Pipe-line SAR ADCs or Bridge-Capacitor SAR ADCs can be a solution to this issue. They help to maintain the unit capacitance of the C-DAC larger than the minimum size required to guarantee matching/accuracy without getting the overall cap requirement too large. However, such ADCs may need complex gain/capacitance value calibrations to run at boot-up and periodically to ensure the accuracy performance of the ADC. This adds significant complexity to ADC design and results in lesser predictability of the overall performance of the ADC.

The disclosed techniques include a method to implement the DAC for an SAR ADC with the benefits mentioned above that a Pipe-line SAR ADC or a Bridge-Capacitor SAR ADC has, but without the need for complex calibration procedures to keep up the performance across PVT conditions. More specifically, the disclosed techniques may be used to configure a DAC that includes a least significant bit (LSB) resistor-based DAC (e.g., R-2R DAC) and a most significant bit (MSB) capacitor-based DAC (C-DAC) that are coupled by a coupling capacitor. Additional techniques for selection of the unit capacitance and coupling capacitance are also disclosed.

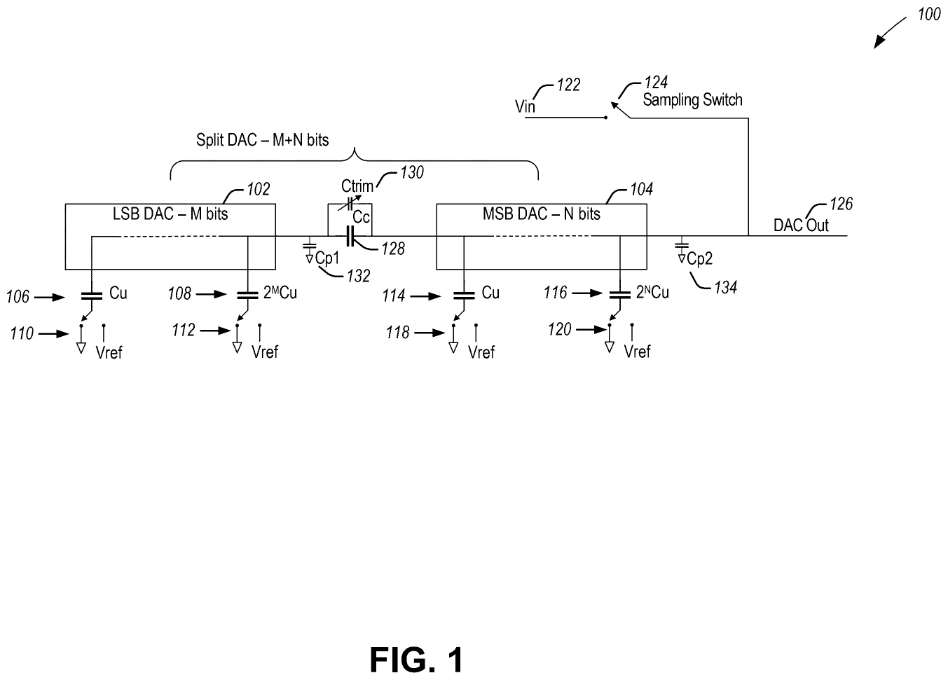

An example solution to form a high-speed, high-accuracy capacitor DAC is shown in FIG. 1. FIG. 1 is a block diagram of a capacitor-based DAC (C-DAC) with M+N bits resolution, in accordance with some embodiments. Referring to FIG. 1, DAC 100 is configured as a split DAC (M+N bits) formed by LSB DAC 102 (e.g., M bits) and MSB DAC 104 (e.g., N bits). The LSB DAC 102 is associated with parasitic capacitance 132, and MSB DAC 104 is associated with parasitic capacitance 134.

In some aspects, both the LSB DAC 102 and the MSB DAC 104 are capacitor-based DACs. For example, LSB DAC 102 includes a plurality of capacitors 106, . . . , 108 that are coupled in parallel. The capacitors 106, . . . , 108 are coupled to a corresponding plurality of digital switches 110, . . . , 112. The MSB DAC 104 includes a plurality of capacitors 114, . . . , 116 that are coupled in parallel. The capacitors 114, . . . , 116 are coupled to a corresponding plurality of digital switches 118, . . . , 120. The digital switches 110, . . . , 112 and 118, . . . , 120 can be configured to select between ground and input digital signals based on reference voltage (Vref) signals. The capacitors 106, . . . , 108 and 114, . . . , 116 can be multiples of a unit capacitance (Cu).

DAC 100 further includes a sampling switch 124 to sample an input voltage (Vin) signal 122 and generate a DAC output signal 126.

In some aspects, the LSB DAC 102 and the MSB DAC 104 are coupled via a coupling capacitor (Cc) 128. A trim capacitor (Ctrim) 130 can be used to trim Cc 128.

DAC 100 is also referred to as bridge C-DAC or Sslit C-DAC. As illustrated in FIG. 1, DAC 100 includes independent binary C-DACs (having the same unit capacitance), which are coupled together using a coupling capacitor Cc. The coupling capacitor attenuates the effective output range of the N-bit binary C-DAC to the left of it, though it uses the same size unit cap and reference voltage that the M-bit MSB binary array uses. In effect, with the correct value of Cc, the overall DAC 100 can be made to function as an N+M bit binary DAC. This bridge capacitor C-DAC structure solves the issue of the substantial total capacitance that a conventional full binary C-DAC requires when designed with a realizable value of a unit capacitor. This architecture can be used in C-DACs that implement 9-bit or higher resolution.

In bridge capacitor-based C-DAC schemes (or its variants) shown in FIG. 1, the value of the coupling capacitance Cc can be used in determining its linearity factors (especially the dynamic non-linearity or DNL). The optimal value of the coupling capacitance Cc can be configured based on one or more of the following:
(a) The unit capacitance used on one or both of the MSB and LSB binary arrays;
(b) The LSB/MSB split in terms of total bits; and
(c) The parasitic capacitance on the top plate of the LSB array (where the Cc connects to the LSB DAC) (e.g., Cp1 in FIG. 1).

With all these effects, even if the same unit capacitor is used for the LSB and MSB arrays (e.g., Cu, as illustrated in FIG. 1), the correct value of Cc comes as a fraction of the unit capacitance used. Also, the value of Cc is sensitive to the parasitics and leakage on the top plate of the LSB array. Therefore, the Cc can be measured and trimmed on the chip. The small value of Cc, its parasitic/leakage sensitivity, and the fact that no direct measurement techniques exist to measure it make the calibration procedure of Cc complex. Such a tailored calibration scheme is run at every cold boot and possibly at regular intervals to keep the voltage/temperature variations in check. Thus, the disadvantages of the bridge capacitor DAC architecture of FIG. 1 can be summarized as follows:
(a) Cc is not the same as the unit capacitance but is a non-integer multiple. This makes maintaining the ratio metric accuracy difficult.
(b) Cc is highly sensitive to the parasitic capacitance 132 (Cp1) on the top plate of the LSB array.
(c) The above two factors mandate the on-chip calibration of Cc in order to maintain its accuracy and keep the DAC linearity errors under control.
(d) The need to maintain the value of Cc within a reasonable fraction above the unit capacitance and the need to reduce the parasitic capacitance Cp1 on the LSB array put constraints on the maximum number of bits that can be put into the LSB array. This configuration reduces the possibility of total capacitance minimization in the MSB array to achieve higher speed, and it also reduces the operating speed of the DAC and the associated ADC.

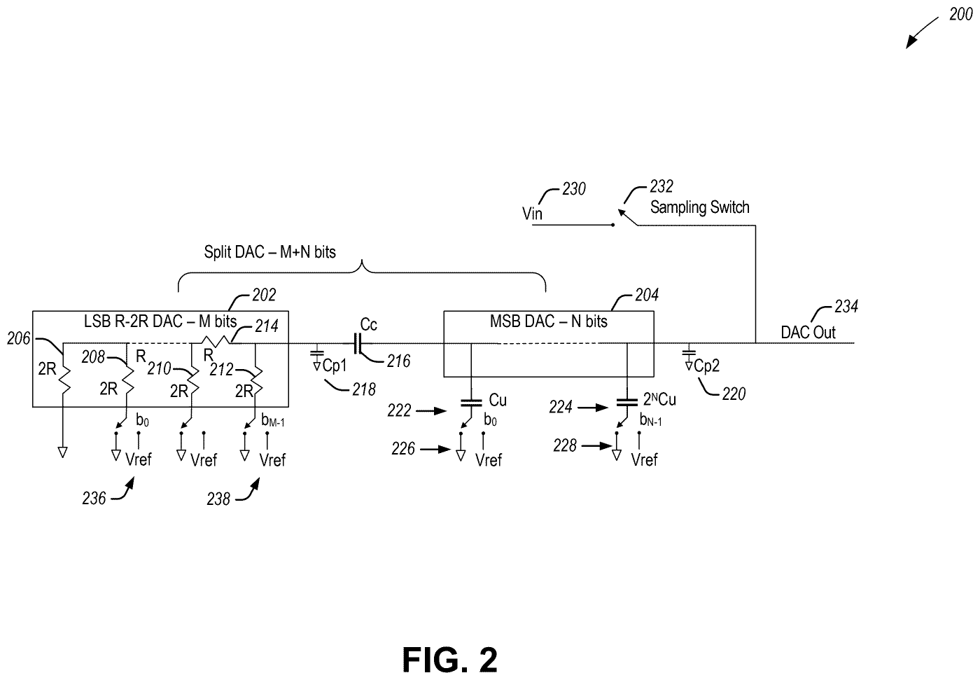

The disclosed techniques (e.g., as illustrated in FIG. 2) can be used to configure a high-resolution, high-speed hybrid DAC structure that can be used in ADCs having greater than 8-bit resolution and operating at speeds greater than 500 mega samples per second (MSPS). The proposed scheme makes use of a hybrid resistor-capacitor DAC structure, as shown in FIG. 2. The LSB bits are implemented via an R-2R structure, and the MSB bits via a binary C-DAC. Both are coupled via a coupling capacitance Cc. The overall DAC has the resolution (in bits) of the R-2R DAC and the C-DAC bits put together. This addresses the drawbacks of the bridge capacitance scheme described in connection with FIG. 1 and can be seen as suitable for high accuracy (greater than 8-bit and up to 12-bit) and high-speed (greater than 500 MSPS) operation.

In some aspects, the disclosed DAC architecture can be used in automotive applications (e.g., in long-reach SerDes transceivers for in-vehicle data transfer).

FIG. 2 is a block diagram of a hybrid DAC structure with a resistive DAC and a C-DAC, effectively generating an equivalent M+N bits master DAC, in accordance with some embodiments. Referring to FIG. 2, DAC 200 (also referred to as master DAC 200) is configured as a split DAC (M+N bits) formed by LSB DAC 202 (e.g., M bits) and MSB DAC 204 (e.g., N bits). The LSB DAC 202 is associated with parasitic capacitance 218, and the MSB DAC 204 is associated with parasitic capacitance 220.

In some aspects, the LSB DAC 202 is configured as a resistor-based DAC, and the MSB DAC 104 is configured as a capacitor-based DAC. For example, LSB DAC 202 includes a first plurality of resistors 206, 208, . . . , 210, and 212 that are coupled in parallel. In some aspects, a second plurality of resistors is coupled in series and with one or more of the first plurality of resistors. For example, resistor 214 is part of the second plurality of resistors and is coupled in series with resistors 210 and 212 of the first plurality of resistors. In some aspects, the first and second plurality of resistors form an R-2R ladder structure configuring the LSB DAC 202. In some aspects, resistors 208, . . . , 212 of the first plurality of resistors are coupled to a corresponding plurality of digital switches 236, . . . , 238.

The MSB DAC 204 includes a plurality of capacitors 222, . . . , 224 that are coupled in parallel. The capacitors 222, . . . , 224 are coupled to a corresponding plurality of digital switches 226, . . . , 228. The digital switches 236, . . . , 238, and 226, . . . , 228 can be configured to select between ground and input digital signals based on reference voltage (Vref) signals. The capacitors 222, . . . , 224 can be multiples of a unit capacitance (Cu).

DAC 200 further includes a sampling switch 232 that samples an input voltage (Vin) signal 230 and generates a DAC output signal 234.

In some aspects, the LSB DAC 202 and the MSB DAC 204 are coupled via a coupling capacitor (Cc) 216 without the use of a trim capacitor.

The disclosed techniques include the hybrid (mixed) DAC structure of FIG. 2, with one part formed as binary weighted C-DAC (e.g., MSB DAC 204, also referred to as C-DAC 204) and another part formed as an R-2R DAC (e.g., LSB DAC 202, also referred to as R-2R DAC 202). The master DAC formed (e.g., DAC 200) functions as an equivalent binary DAC with effective resolution of the C-DAC and R-2R DAC bits put together. The C-DAC 204 and the R-2R DAC 202 are coupled together via a coupling capacitor Cc 216. The R-2R DAC functions as the LSB bit of the master DAC 200, and the matching requirement can be limited to the resolution (in number of bits) within the R-2R DAC. The C-DAC serves as the MSB bits of the master DAC, and the matching requirement of the capacitor units within the C-DAC corresponds to the total resolution (in number of bits) of the master DAC itself. In some aspects, the speed requirements on both of the DACs (the C-DAC 204 and the R-2R DAC 202) are the same and correspond to the master DAC speed bit conversion speed (or the ADC bit conversion speed that employs the master DAC).

In some aspects, the resistor matching (for resistors like thin film) can give up to 7-bit resolution with the R-2R DAC structure, as shown in Table 1 below. Thus, employing the R-2R DAC for LSB bits dramatically reduces the total capacitance in the C-DAC with a reliable capacitance unit. Also, the parasitic capacitance associated with the thin-film resistor structures is negligible. In this regard, the R-2R DAC can operate at very high speeds, making this hybrid DAC structure suitable for ADCs operating above 500 MSPS speed.

In some embodiments targeting a 10-bit ADC with 500 MSPS sampling speed, 5 bits in the LSB R-2R DAC and 5 bits in the MSB C-DAC can be used. Table 2 summarizes the advantage that can be obtained in the total capacitance value at the MSB array of the DAC via this scheme over the bridge capacitance scheme of FIG. 1.

In the proposed FIG. 2 architecture, the coupling capacitance value needed can be the same as the unit capacitance of the MSB array. Matching this with the MSB capacitor array becomes trivial as all capacitances of the C-DAC are realized using the same unit capacitance.

In some aspects, the settling of the voltage across Cc can be based on the output impedance offered by the R-2R DAC (which can be calculated as R). Once the Cc is ultimately settled, the parasitic capacitances on the R-2R DAC nodes can become irrelevant in determining the value of the coupling capacitance value. This can be beneficial as the coupling capacitance value does not need to be calibrated on-chip.

In some aspects, the following configurations can be used to select the unit capacitance (Cu), the coupling capacitance (Cc), and the resistive value (e.g., R) of the R-2R DAC associated with the DAC 200.

(a) The unit capacitance (Cu) of the MSB C-DAC can be determined based on the matching requirement (e.g., based on a dynamic non-linearity (DNL) specification) and settling time during sampling of the input voltage (Vin). In some aspects, the higher the Cu, the better the matching and the lower the DNL. However, a higher Cu increases the settling time.

(b) The coupling capacitance (Cc) value can be configured to be equal to the unit capacitance (Cu).

(c) The unit resistance value (R) can be selected based on the R*Cc setting time. In some aspects, the lower the value of R, the smaller the settling time. However, a lower R increases the DC current drawn from the Vref nodes. In some aspects, the drive capacity of the Vref node (while maintaining the required accuracy) sets the lower limit for the unit resistance (R).

In some aspects, the DAC architecture of FIG. 2 is associated with the following advantages over the bridge-capacitance DAC of FIG. 1:

(a) The R-2R DAC of FIG. 2 can be used to implement, for example, 6 to 7 bits of resolution while still maintaining the required accuracy and speed levels. This provides a very efficient way of splitting the bits between the C-DAC and the R-2R DAC, resulting in a lower number of total capacitance (this is illustrated in Table 2 below). Lower capacitance means the proposed scheme can work at higher speeds than existing schemes.

(b) The coupling capacitance value (Cc) used can be the same as the MSB DAC unit capacitance Cu, which can contribute to achieving optimal matching and accuracy.

(c) The coupling capacitance value (Cc) can be independent of the parasitic capacitance on both the LSB (R-2R DAC) side and the MSB (C-DAC) side (as it can be equal to the unit capacitance Cu).

(d) The above-listed advantages can ensure no calibration procedure needs to be employed for the coupling capacitance Cc. The coupling capacitor (Cc) calibration can be a significant implementation complexity and source of inaccuracy in conventional bridge capacitance DAC structures (e.g., DAC 100 of FIG. 1).

(e) The R-2R DAC offers the same impedance on all the nodes, which can ensure the setting performance is uniform across the DAC.

The following configurations can be used in connection with resistance matching in the R-2R DAC of DAC 200 in FIG. 2.

Table 1 illustrates mismatch data of thin-film resistors. It can be seen that 7-bit matching can be achieved. That means the LSB R-2R DAC can be designed with up to 7 bits, which can lower the capacitance value used on the MSB CDAC.

TABLE 1

| Parameters of Thin-film | | |
|---|---|---|
| Resistor used in R-2R LS | Value | |
| Dimension (W × L) | 0.72u × 2u | |
| Parasitic Capacitance | 544 | aF |
| Resistance (Mean) | 993 | Ohms |
| Resistance standard | 2.48 | Ohms |
| deviation (1-Sigma) | | |
| DAC effective resolution | 7 | bits |
| with 3-sigma variation in bits | | |

Below, Table 2 summarizes the total MSB array capacitance (sampling capacitance) to be used for comparable linearity results between the proposed architecture of FIG. 2 and the bridge capacitance architecture of FIG. 1. For achieving 0.6 LSB DNL, the proposed FIG. 2 architecture provides approximately four times reduction in the size of the MSB DAC when compared to the bridge capacitor DAC of FIG. 1 without any calibration scheme applied.

Table 2: Total Sampling capacitance (total MSB array capacitance) value comparison for the same DNL performance between the proposed scheme and the FIG. 1 scheme.

TABLE 2
DNL Target = 0.6 LSB.
Top plate parasitic (Cp1) of LSB DAC is assumed = 7% of the cap value.
Unti Cap(Cu) = 5fF.
Mismatch (standard deviation) per 1fF = 1%

| | MSB Number | LSB Number | Total MSB |
|---|---|---|---|
| Scheme | of bits | of bits | C-DAC Cap |
| Bridge C-DAC* | 8 | 2 | 2555 |
| Proposed Hybrid | 6 | 4 | 635 |
| C-R DAC | | | |

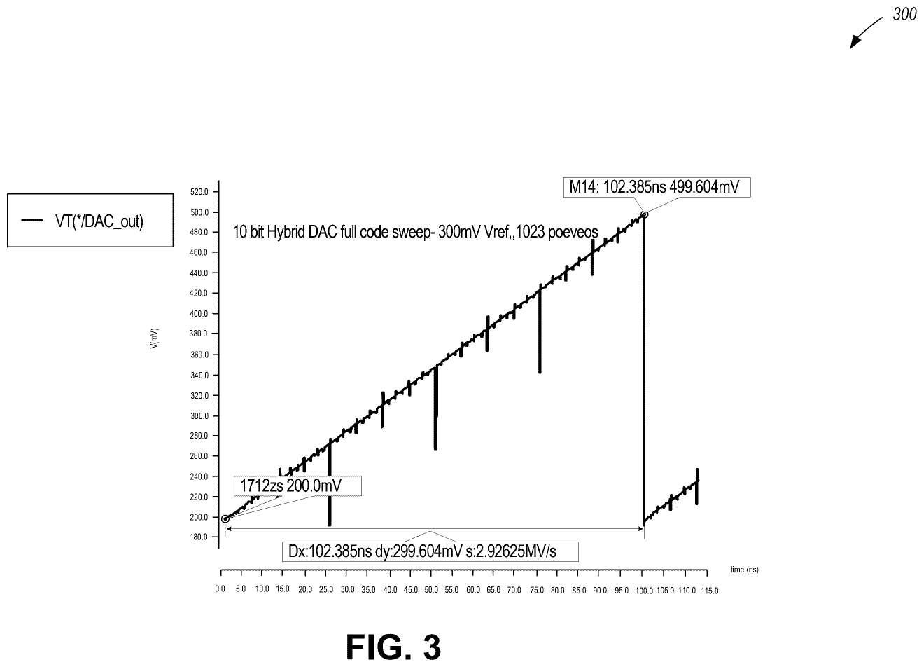

FIG. 3 illustrates graph 300 of a 10-bit hybrid capacitive-resistive (C-R) DAC output with full code sweep, in accordance with some embodiments.

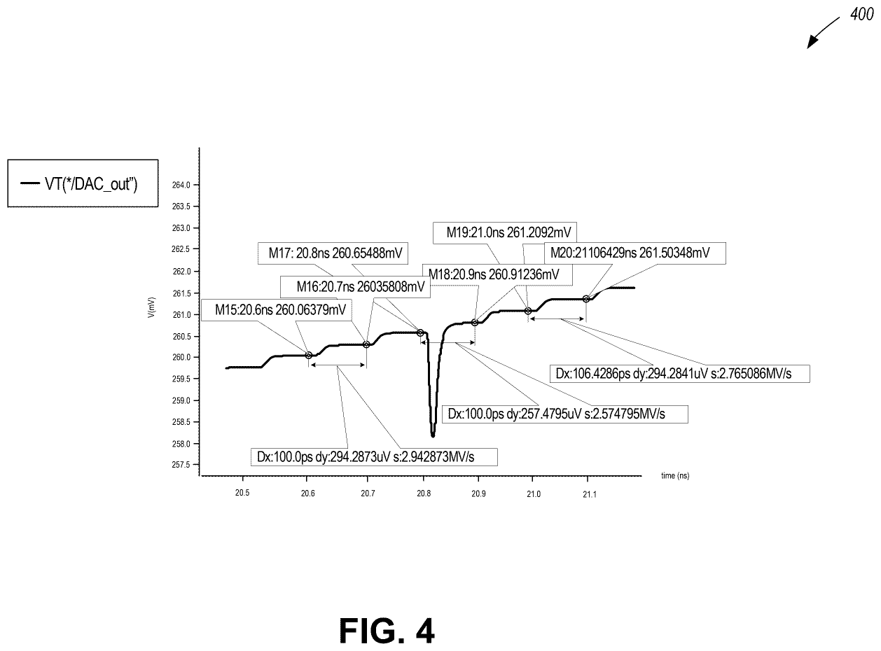

FIG. 4 illustrates graph 400 of a zoomed version of DAC output showing the LSB switching of C-DAC, in accordance with some embodiments.

FIG. 3 and FIG. 4 show the full code sweep of a 10-bit hybrid ADC, realized with 5-bit LSBs in R-2R DAC and 5-bit MSBs in C-DAC. The Vref voltage of 300 mV is the full range of this DAC, and the LSB size is 293 uV. The per DAC step time is 100 ps. R-2R DAC unit size is 1 kilo Ohm, and a C-DAC unit size of 5 fF is used in this simulation.

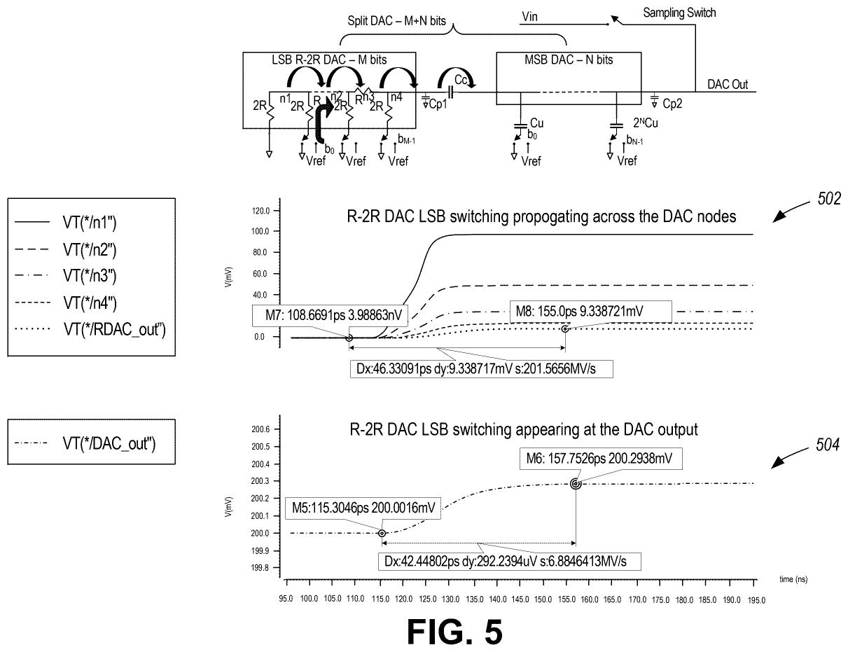

Voltage settling dynamics of the DAC (e.g., R-2R DAC LSB step propagation) are illustrated in FIG. 5.

FIG. 5 illustrates graphs 502 and 504 of the least significant bit (LSB) step change propagation delay across a 5-bit R-2R DAC up to the final DAC output, in accordance with some embodiments.

FIG. 5 illustrates that the total propagation delay for the LSB step to reach the output is ˜50 ps. This is a small number since the per-bit conversion time allocated for a 500 MSPS ADC is about 150 ps.

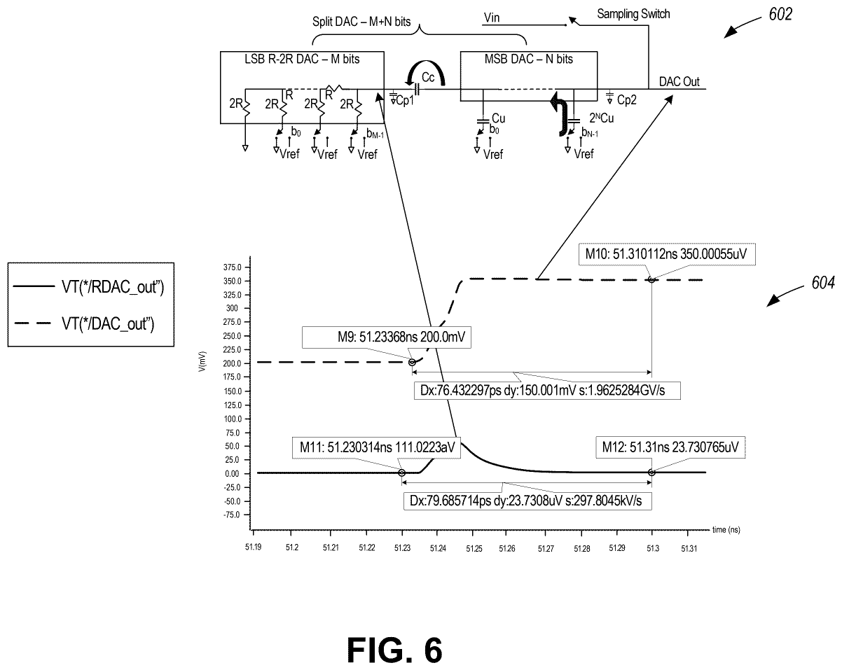

Voltage settling dynamics of the DAC (e.g., settling across the Cc for C-DAC MSB change) are illustrated in FIG. 6.

FIG. 6 illustrates graphs 602 and 604 of voltage settling across the coupling capacitance Cc for a C-DAC most significant bit (MSB) step change, in accordance with some embodiments.

FIG. 6 illustrates that the settling across Cc depends on the Cc value and the R-2R DAC output impedance (which is equal to the unit resistance value R). The settling of MSB switching (to 0.1 LSB error) takes around 80 ps, which is an acceptable low threshold.

In some aspects, the disclosed techniques include a hybrid DAC structure with part of the resolution implemented via an R-2R DAC and part via binary C-DAC. As explained above, the DAC architecture (e.g., DAC 200 of FIG. 2) can achieve a 10-bit resolution with a reasonable total sampling capacitor value of ˜635 fF. In comparison, a bridge C-DAC, without calibration, would take 2555 fF for a similar performance. The disclosed DAC can achieve high speeds of ˜100 ps per bit conversion, making it suitable for building high-speed ADCs operating at greater than 500 MSPS. The settling behavior of the DAC is presented in FIGS. 3-6 to illustrate this.

The following key benefits are associated with the disclosed DAC 200:

(a) Splits the binary array to significantly reduce the overall sampling capacitance value (or MSB array total capacitance). This provides significant speed improvement in ADCs, which resolve more than 8 bits.

(b) No complex on-chip calibration is required. The existing schemes may need to implement complex on-chip calibration schemes to keep the DNL under control.

(c) Higher bit resolution (up to 7 bits) can be implemented on the LSB array. In bridge-capacitor DAC schemes, higher bits on the MSB array mean finer on-chip trimming steps in the Cc value. Having higher bits on the LSB array dramatically helps to reduce the sampling capacitor on the MSB C-DAC array and helps to achieve higher speed.

(d) Less sensitivity to the parasitic capacitance (as long as switching activity settles) and leakage on the LSB array. No VT drift adjustments are required as compared to existing schemes.

(e) Uniform resistor and capacitor units are used across the structure, which assists with improved matching and maintaining DNL/INL error that is low across process corners. The existing scheme can realize Cc, which is a fractional multiple of the unit capacitor, and it can be challenging to get accurate matching.

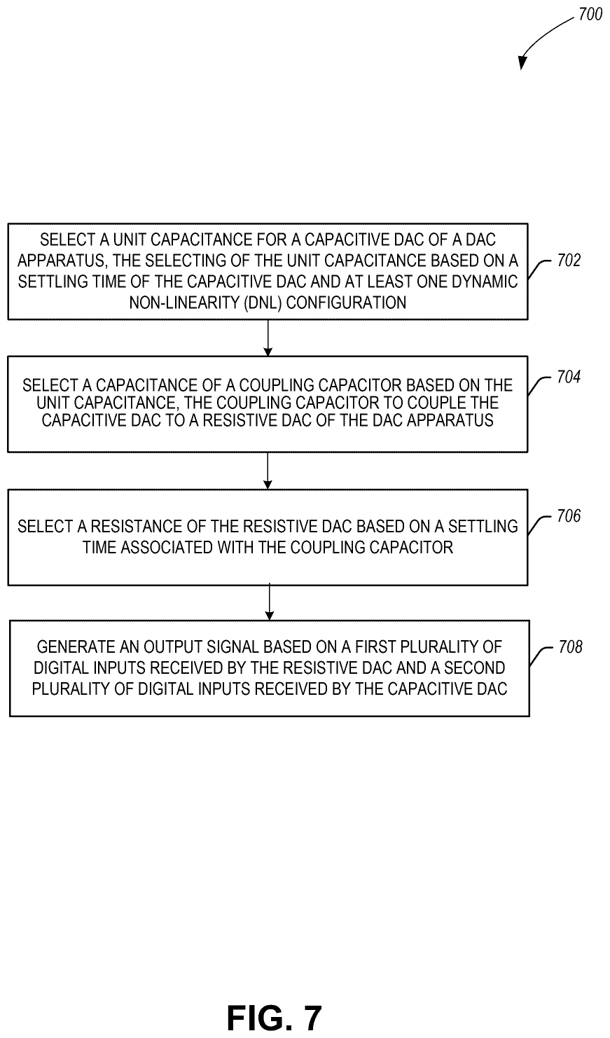

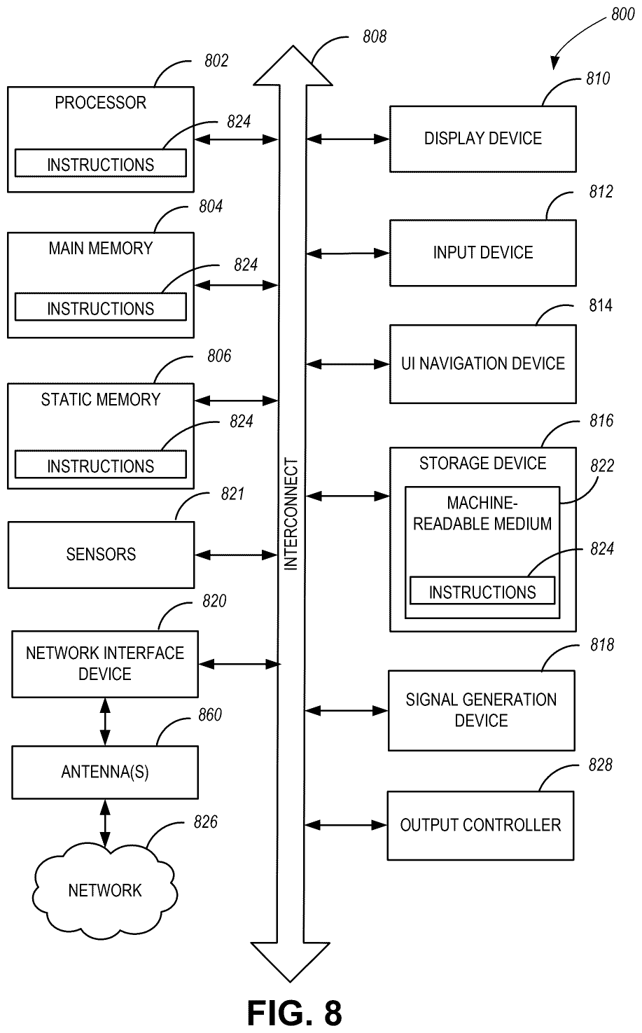

FIG. 7 is a flow diagram of an example method for configuring a digital-to-analog converter (DAC) apparatus, in accordance with some embodiments. Referring to FIG. 7, method 700 includes operations 702, 704, 706, and 708, which may be executed by a processor, an embedded controller, a receiver circuit, a transceiver circuit, or another processor of a computing device (e.g., hardware processor 802 of machine 800 illustrated in FIG. 8, which can include one or more of the circuits discussed in connection with FIGS. 1-6). In some embodiments, one or more of the circuits discussed in connection with FIGS. 1-6 can perform the functionalities listed in FIG. 7, as well as one or more of the examples listed below.

At operation 702, a unit capacitance is selected for a capacitive DAC of a DAC apparatus (e.g., DAC 200). In some aspects, the selection of the unit capacitance is based on a settling time of the capacitive DAC and at least one dynamic non-linearity (DNL) configuration.

At operation 704, the capacitance of a coupling capacitor (e.g., Cc of FIG. 2) is selected based on the unit capacitance. The coupling capacitor is to couple the capacitive DAC to a resistive DAC of the DAC apparatus.

At operation 706, a resistance of the resistive DAC is selected based on a settling time associated with the coupling capacitor.

At operation 708, an output signal is generated based on a first plurality of digital inputs received by the resistive DAC and a second plurality of digital inputs received by the capacitive DAC.

FIG. 8 illustrates a block diagram of an example machine 800 upon which any one or more of the techniques (e.g., methodologies) discussed herein may perform. In alternative embodiments, the machine 800 may operate as a standalone device or may be connected (e.g., networked) to other machines. In a networked deployment, machine 800 may operate in the capacity of a server machine, a client machine, or both in server-client network environments. In an example, machine 800 may function as a peer machine in a peer-to-peer (P2P) (or other distributed) network environment. The machine 800 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 800 may include a hardware processor 802 (e.g., a central processing unit (CPU), a graphics processing unit (GPU), a hardware processor core, or any combination thereof), a main memory 804, and a static memory 806, some or all of which may communicate with each other via an interlink (e.g., bus) 808. In some aspects, the main memory 804, the static memory 806, or any other type of memory (including cache memory) used by machine 800 can be configured based on the disclosed techniques or can implement the disclosed memory devices.

Specific examples of main memory 804 include Random Access Memory (RAM) and semiconductor memory devices, which may include, in some embodiments, storage locations in semiconductors such as registers. Specific examples of static memory 806 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 800 may further include a display device 810, an input device 812 (e.g., a keyboard), and a user interface (UI) navigation device 814 (e.g., a mouse). In an example, the display device 810, the input device 812, and the UI navigation device 814 may be a touchscreen display. The machine 800 may additionally include a storage device (e.g., drive unit or another mass storage device) 816, a signal generation device 818 (e.g., a speaker), a network interface device 820, and one or more sensors 821, such as a global positioning system (GPS) sensor, compass, accelerometer, or other sensors. The machine 800 may include an output controller 828, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 802 and/or instructions 824 may comprise processing circuitry and/or transceiver circuitry.

The storage device 816 may include a machine-readable medium 822 on which one or more sets of data structures or instructions 824 (e.g., software) embodying or utilized by any one or more of the techniques or functions described herein can be stored. Instructions 824 may also reside, completely or at least partially, within the main memory 804, within static memory 806, or the hardware processor 802 during execution thereof by the machine 800. In an example, one or any combination of the hardware processor 802, the main memory 804, the static memory 806, or the storage device 816 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 822 is illustrated as a single medium, the term “machine-readable medium” may include a single medium or multiple media (e.g., a centralized or distributed database and/or associated caches and servers) configured to store instructions 824.

An apparatus of machine 800 may be one or more of a hardware processor 802 (e.g., a central processing unit (CPU), a graphics processing unit (GPU), a hardware processor core, or any combination thereof), a main memory 804 and a static memory 806, one or more sensors 821, a network interface device 820, one or more antennas 860, a display device 810, an input device 812, a UI navigation device 814, a storage device 816, instructions 824, a signal generation device 818, and an output controller 828. The apparatus may be configured to perform one or more of the methods and/or operations disclosed herein. The apparatus may be intended as a component of machine 800 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 800 and that causes machine 800 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 824 may further be transmitted or received over a communications network 826 using a transmission medium via the network interface device 820 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.8.4 family of standards, a Long Term Evolution (LTE) family of standards, a Universal Mobile Telecommunications System (UMTS) family of standards, peer-to-peer (P2P) networks, among others.

In an example, the network interface device 820 may include one or more physical jacks (e.g., Ethernet, coaxial, or phone jacks) or one or more antennas to connect to the communications network 826. In an example, the network interface device 820 may include one or more antennas 860 to wirelessly communicate using at least one single-input multiple-output (SIMO), multiple-input multiple-output (MIMO), or multiple-input single-output (MISO) techniques. In some examples, the network interface device 820 may wirelessly communicate using multiple-user MIMO techniques. The term “transmission medium” shall be taken to include any intangible medium that can store, encode, or carry instructions for execution by the machine 800 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is a digital-to-analog converter (DAC) circuit comprising a first plurality of resistors comprising a plurality of first terminals and a plurality of second terminals, the first plurality of resistors coupled in parallel via the plurality of second terminals of the first plurality of resistors; a plurality of capacitors comprising a corresponding plurality of first terminals and a corresponding plurality of second terminals, the plurality of capacitors coupled in parallel via the plurality of second terminals of the plurality of capacitors; and a coupling capacitor comprising a first terminal and a second terminal, the first terminal coupled to the plurality of second terminals of the first plurality of resistors, and the second terminal coupled to the plurality of second terminals of the plurality of capacitors.

In Example 2, the subject matter of Example 1 includes a first plurality of digital inputs, a digital input of the first plurality of digital inputs coupled to a first terminal of the plurality of first terminals of the first plurality of resistors.

In Example 3, the subject matter of Example 2 includes a second plurality of digital inputs, a digital input of the second plurality of digital inputs coupled to a first terminal of the plurality of first terminals of the plurality of capacitors.

In Example 4, the subject matter of Example 3 includes subject matter where a digital input of the first plurality of digital inputs and the second plurality of digital inputs comprises a digital switch.

In Example 5, the subject matter of Example 4 includes subject matter where the digital switch comprises a first terminal coupled to ground and a second terminal to receive a reference voltage signal.

In Example 6, the subject matter of Examples 4-5 includes a sampling switch, the sampling switch comprising a first terminal to receive an input voltage signal.

In Example 7, the subject matter of Example 6 includes subject matter where the sampling switch further comprises a second terminal, the second terminal coupled to an output terminal of the DAC circuit, and the plurality of second terminals of the plurality of capacitors.

In Example 8, the subject matter of Examples 1-7 includes a second plurality of resistors, the second plurality of resistors coupled in series, and a resistor of the second plurality of resistors coupled in series with at least two resistors of the first plurality of resistors.

In Example 9, the subject matter of Example 8 includes subject matter where the DAC circuit comprises a system-on-chip (SoC), the SoC comprising an integrated circuit (IC), the IC comprising two or more of the first plurality of resistors, the second plurality of resistors, the plurality of capacitors, and the coupling capacitor.

In Example 10, the subject matter of Example 9 includes subject matter where the SoC further comprises a connector, and wherein the connector conforms with at least one of Universal Serial Bus (USB), High-Definition Multimedia Interface (HDMI), Thunderbolt, Peripheral Component Interconnect Express (PCIe), and Ethernet specifications.

Example 11 is a digital-to-analog converter (DAC) apparatus comprising a resistive DAC circuit comprising a first plurality of resistors coupled in parallel and a first plurality of input switches coupled to the first plurality of resistors; a capacitive DAC circuit comprising a plurality of capacitors coupled in parallel, and a second plurality of input switches coupled to the plurality of resistors; and a coupling capacitor comprising a first terminal coupled to the resistive DAC circuit and a second terminal coupled to the capacitive DAC circuit.

In Example 12, the subject matter of Example 11 includes subject matter where the resistive DAC circuit comprises a second plurality of resistors coupled in series, and a resistor of the second plurality of resistors coupled in series with at least two resistors of the first plurality of resistors.

In Example 13, the subject matter of Example 12 includes subject matter where the resistive DAC is an R-2R DAC, wherein a resistor of the second plurality of resistors has a resistance of R, and wherein a resistor of the second plurality of resistors has a resistance of 2R.

In Example 14, the subject matter of Examples 11-13 includes subject matter where a capacitor of the plurality of capacitors has a capacitance that is a multiple of a unit capacitance Cu.

In Example 15, the subject matter of Example 14 includes subject matter where a capacitance of the coupling capacitor is equal to the unit capacitance Cu.

In Example 16, the subject matter of Examples 11-15 includes subject matter where an input switch of the first plurality of input switches is coupled to a digital input of a first plurality of digital inputs. An input switch of the second plurality of input switches is coupled to a digital input of a second plurality of digital inputs.

In Example 17, the subject matter of Example 16 includes subject matter where the first plurality of digital inputs forms least significant bits (LSB) of a digital input signal and wherein the second plurality of digital inputs forms most significant bits (MSB) of the digital input signal.

In Example 18, the subject matter of Example 17 includes a sampling switch comprising a first terminal and a second terminal, the first terminal to receive an input voltage signal, the second terminal coupled to an output terminal of the DAC apparatus, and the plurality of capacitors, and the output terminal to output an analog signal corresponding to the digital input signal.

In Example 19, the subject matter of Example 18 includes a system-on-chip (SoC), the SoC comprising an integrated circuit (IC), and the IC comprising two or more of the resistive DAC, the capacitive DAC, the coupling capacitor, and the sampling switch.

Example 20 is a method for configuring a digital-to-analog converter (DAC) apparatus, the method comprising selecting a unit capacitance for a capacitive DAC of the DAC apparatus, the selecting of the unit capacitance based on a settling time of the capacitive DAC and at least one dynamic non-linearity (DNL) configuration; selecting a capacitance of a coupling capacitor based on the unit capacitance, the coupling capacitor to couple the capacitive DAC to a resistive DAC of the DAC apparatus; selecting a resistance of the resistive DAC based on a settling time associated with the coupling capacitor; and generating an output signal based on a first plurality of digital inputs received by the resistive DAC and a second plurality of digital inputs received by the capacitive DAC.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A digital-to-analog converter (DAC) circuit comprising:
a first plurality of resistors comprising a plurality of first terminals and a plurality of second terminals, the first plurality of resistors that are via the plurality of second terminals of the first plurality of resistors;
a plurality of capacitors comprising a corresponding plurality of first terminals and a corresponding plurality of second terminals, the plurality of capacitors coupled in parallel via the plurality of second terminals of the plurality of capacitors; and
a coupling capacitor comprising a first terminal and a second terminal, the first terminal coupled to the plurality of second terminals of the first plurality of resistors, and the second terminal coupled to the plurality of second terminals of the plurality of capacitors.

2. The DAC circuit of claim 1, further comprising:
a first plurality of digital inputs, a digital input of the first plurality of digital inputs coupled to a first terminal of the plurality of first terminals of the first plurality of resistors.

3. The DAC circuit of claim 2, further comprising:
a second plurality of digital inputs, a digital input of the second plurality of digital inputs coupled to a first terminal of the plurality of first terminals of the plurality of capacitors.

4. The DAC circuit of claim 3, wherein a digital input of the first plurality of digital inputs and the second plurality of digital inputs comprises a digital switch.

5. The DAC circuit of claim 4, wherein the digital switch comprises a first terminal coupled to ground and a second terminal to receive a reference voltage signal.

6. The DAC circuit of claim 4, further comprising:
a sampling switch, the sampling switch comprising a first terminal to receive an input voltage signal.

7. The DAC circuit of claim 6, wherein the sampling switch further comprises a second terminal, the second terminal coupled to an output terminal of the DAC circuit and the plurality of second terminals of the plurality of capacitors.

8. The DAC circuit of claim 1, further comprising:
a second plurality of resistors, the second plurality of resistors coupled in series, and a resistor of the second plurality of resistors coupled in series with at least two resistors of the first plurality of resistors.

9. The DAC circuit of claim 8, wherein the DAC circuit comprises a system-on-chip (SoC), the SoC comprising an integrated circuit (IC), the IC comprising two or more of the first plurality of resistors, the second plurality of resistors, the plurality of capacitors, and the coupling capacitor.

10. The DAC circuit of claim 9, wherein the SoC further comprises a connector, and wherein the connector conforms with at least one of Universal Serial Bus (USB), High-Definition Multimedia Interface (HDMI), Thunderbolt, Peripheral Component Interconnect Express (PCIe), and Ethernet specifications.

11. A digital-to-analog converter (DAC) apparatus comprising:
a resistive DAC circuit comprising a first plurality of resistors coupled in parallel, and a first plurality of input switches coupled to the first plurality of resistors;
a capacitive DAC circuit comprising a plurality of capacitors coupled in parallel, and a second plurality of input switches coupled to the plurality of resistors; and
a coupling capacitor comprising a first terminal coupled to the resistive DAC circuit and a second terminal coupled to the capacitive DAC circuit.

12. The DAC apparatus of claim 11, wherein the resistive DAC circuit comprises:
a second plurality of resistors coupled in series, and a resistor of the second plurality of resistors coupled in series with at least two resistors of the first plurality of resistors.

13. The DAC apparatus of claim 12, wherein the resistive DAC is an R-2R DAC, wherein a resistor of the second plurality of resistors has a resistance of R, and wherein a resistor of the second plurality of resistors has a resistance of 2R.

14. The DAC apparatus of claim 11, wherein a capacitor of the plurality of capacitors has a capacitance that is a multiple of a unit capacitance Cu.

15. The DAC apparatus of claim 14, wherein a capacitance of the coupling capacitor is equal to the unit capacitance Cu.

16. The DAC apparatus of claim 11, wherein:
an input switch of the first plurality of input switches is coupled to a digital input of a first plurality of digital inputs; and
an input switch of the second plurality of input switches is coupled to a digital input of a second plurality of digital inputs.

17. The DAC apparatus of claim 16, wherein the first plurality of digital inputs forms least significant bits (LSB) of a digital input signal, and wherein the second plurality of digital inputs forms most significant bits (MSB) of the digital input signal.

18. The DAC apparatus of claim 17, further comprising:
a sampling switch comprising a first terminal and a second terminal, the first terminal to receive an input voltage signal, the second terminal coupled to an output terminal of the DAC apparatus and the plurality of capacitors, and the output terminal to output an analog signal corresponding to the digital input signal.

19. The DAC apparatus of claim 18, comprising a system-on-chip (SoC), the SoC comprising an integrated circuit (IC), and the IC comprising two or more of the resistive DAC, the capacitive DAC, the coupling capacitor, and the sampling switch.

20. A method for configuring a digital-to-analog converter (DAC) apparatus, the method comprising:
selecting a unit capacitance for a capacitive DAC of the DAC apparatus, the selecting of the unit capacitance based on a settling time of the capacitive DAC and at least one dynamic non-linearity (DNL) configuration;
selecting a capacitance of a coupling capacitor based on the unit capacitance, the coupling capacitor to couple the capacitive DAC to a resistive DAC of the DAC apparatus;
selecting a resistance of the resistive DAC based on a settling time associated with the coupling capacitor; and
generating an output signal based on a first plurality of digital inputs received by the resistive DAC and a second plurality of digital inputs received by the capacitive DAC.
